(19) United States
(12) Patent Application Publication
(10) Pub. No.: US 2023/0283090 A1
(43) Pub. Date: Sep. 7, 2023

(54) CASE DEVICE AND METHOD PRESENTING CHARGING FUNCTION

(71) Applicant: Samsung Electronics Co., Ltd., Gyeonggi-do (KR)

(72) Inventors: Jongmin YOON, Gyeonggi-do (KR); Sungkwang YANG, Gyeonggi-do (KR); Jungkeun LEE, Gyeonggi-do (KR)

(21) Appl. No.: 18/195,503

(22) Filed: May 10, 2023

Related U.S. Application Data
(63) Continuation of application No. PCT/KR2022/001846, filed on Feb. 7, 2022.

(30) Foreign Application Priority Data
Feb. 8, 2021 (KR) 10-2021-0017616

(51) Int. Cl. H02J 7/00; G06F 1/20; G06F 1/16; H01M 10/63; H01M 10/623

(52) U.S. Cl. CPC H02J 7/0044; G06F 1/203; G06F 1/1628; H01M 10/63; H01M 10/623; G06F 1/163; H10N 10/10

(57) ABSTRACT

A case device for presenting a charging function of various embodiments of the present disclosure may include a housing including an internal space for accommodating a wearable device, a communication interface for presenting a wired or wireless connection with the wearable device, at least one accommodating groove formed in the internal space for accommodating the wearable device, at least one thermoelectric module disposed to be partially exposed through the at least one accommodating groove, a heat radiating member disposed adjacent to the at least one thermoelectric module, a battery disposed inside the housing, and at least one processor electrically connected to the communication interface, the at least one thermoelectric module, the heat radiating member, and the battery. The at least one processor may acquire state information of the wearable device, and control the at least one thermoelectric module, based on the state information of the wearable device.

### CROSS-REFERENCE TO RELATED APPLICATION(S)

This application is a continuation of PCT International Application No. PCT/KR2022/001846, which was filed on Feb. 7, 2022, and claims priority to Korean Patent Application No. 10-2021-0017616, filed on Feb. 8, 2021, in the Korean Intellectual Property Office, the disclosures of which are incorporated by reference herein their entirety.

### BACKGROUND

### Technical Field

Various embodiments of the present disclosure relate to a case device and method for presenting a charging function.

### Description of Related Art

With the growth of technologies, wearable electronic devices such as a head-mounted devices (HMD), a glasses-type devices, contact lens-type devices, a ring-type devices, and a smart watches (or bands) are provided. These wearable electronic devices are directly worn on the human body, which may improve portability and user accessibility. Wearable electronic devices (hereinafter, a wearable device) may also be provided with a protective case (hereinafter, a case device) for storage and charging.

The wearable device may provide various functions. For example, the wearable device may provide a virtual reality (VR) function, an augmented reality (AR) function, a short-range wireless communication (e.g., Bluetooth, Wi-Fi or near field communication (NFC)) function, or an electronic payment function. As wearable devices are utilized for functions of greater number and complexity, there may be a corresponding increase in the quantity of heat generated by components of the wearable device.

When a wearable device is stowed in a case device, it may be difficult to dissipate heat generated from operation of the components of the wearable device and/or the case device, because of the sealed internal space of the case device. The more difficult it is to dissipate the heat generated by the components of the wearable device, the more difficult it is to decrease a temperature of the wearable device. As a result, components of the wearable device may be damaged, or their lifespan may be reduced.

### SUMMARY

Various embodiments of the present disclosure may present a case device capable of dissipating heat generated in a wearable device, through a thermoelectric module of the case device.

A case device for presenting a charging function of various embodiments of the present disclosure may include a housing including an internal space for accommodating a wearable device, a communication interface for presenting a wired or wireless connection with the wearable device, at least one accommodating groove formed in the internal space for accommodating the wearable device, at least one thermoelectric module disposed to be partially exposed through the at least one accommodating groove, a heat radiating member disposed adjacent to the at least one thermoelectric module, a battery disposed inside the housing, and at least one processor electrically connected to the communication interface, the at least one thermoelectric module, the heat radiating member, and the battery. The at least one processor may acquire state information of the wearable device, and control the at least one thermoelectric module, based on the state information of the wearable device.

A case device for presenting a charging function of various embodiments of the present disclosure may include a housing including an internal space for accommodating a wearable device, at least one accommodating groove formed in the internal space and accommodating the wearable device and dissipating a heat provided from the wearable device, and a heat radiating member disposed in a position corresponding to the at least one accommodating groove and exposed at least partially.

A method for operating a case device having at least one thermoelectric module of various embodiments of the present disclosure may include acquiring state information of a wearable device accommodated in the case device, and controlling the at least one thermoelectric module disposed adjacent to the wearable device, based on the state information of the wearable device.

According to various embodiments disclosed in the present document, a case device may limit an increase of a temperature of the wearable device caused by a heat generation of the wearable device, to maintain component performance of the wearable device.

Also, according to various embodiments disclosed in the present document, the case device may solve a heat radiating problem caused by a heat generation of the case device and a heat radiating problem caused by a heat generation of the wearable device, through a heat radiating structure including a thermoelectric module and a slit structure.

### BRIEF DESCRIPTION OF THE DRAWINGS

FIG. 1A is a perspective view of a case device in which a wearable device is accommodated according to an embodiment.

FIG. 1B is a side view of a case device in which a wearable device is accommodated according to an embodiment.

FIG. 1C is a rear view of a case device according to an embodiment.

FIG. 2 is a diagram illustrating a wearable device according to an embodiment.

FIG. 3 is a block diagram illustrating component elements of a case device according to an embodiment.

FIG. 4A is a perspective diagram illustrating an arrangement relationship between a thermoelectric module and a heat radiating member which are disposed inside a case device according to an embodiment.

FIG. 4B is an exploded view of a case device including a thermoelectric module according to an embodiment.

FIG. 4C is an exploded view of a case device including a heat radiating member according to another embodiment.

FIG. 5 is a flowchart illustrating a method of limiting a temperature increase of a wearable device through a case device including a thermoelectric module according to an embodiment.

FIG. 6 is an operation flowchart illustrating a method of limiting a temperature increase of a wearable device through a case device including a thermoelectric module according to an embodiment.

FIG. 7 is a diagram illustrating a network environment including a case device according to various embodiments.

FIG. 8 is a block diagram of a power management module and a battery according to various embodiments.

### DETAILED DESCRIPTION

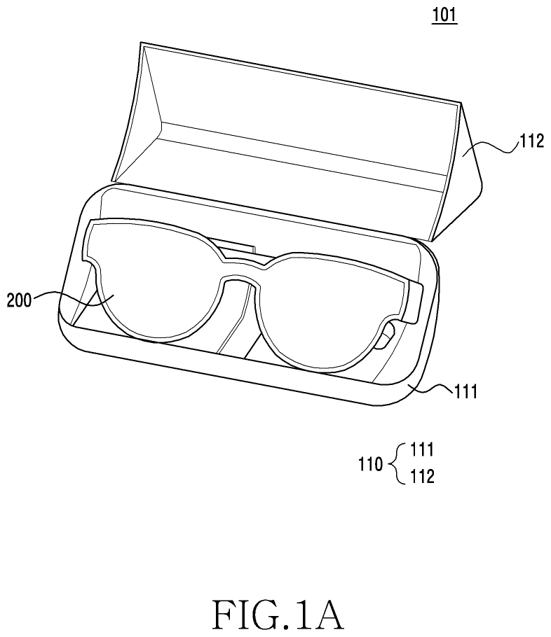

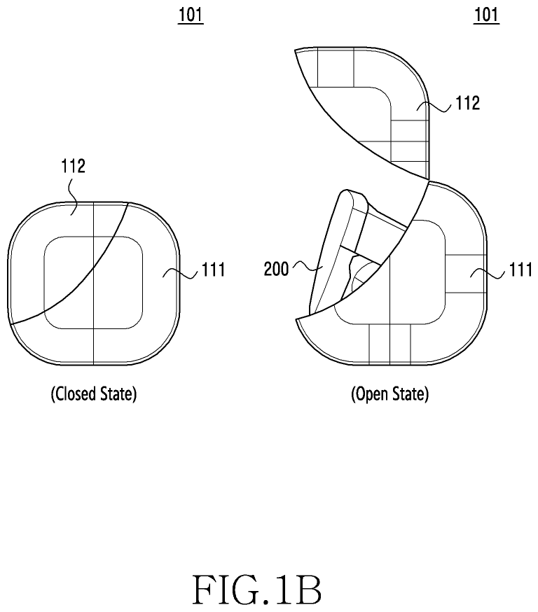

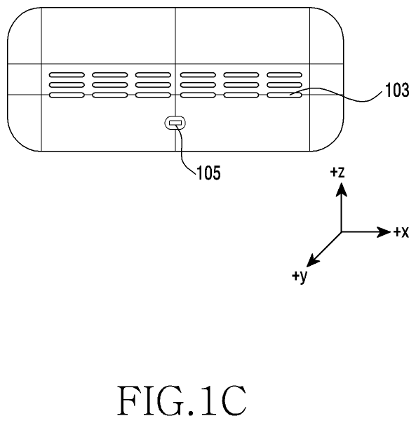

FIG. 1A is a perspective view of a case device 101 in which a wearable device 200 is disposed, according to an embodiment, and FIG. 1B is a side view of the case device 101 in which the wearable device 200 is disposed, according to an embodiment.

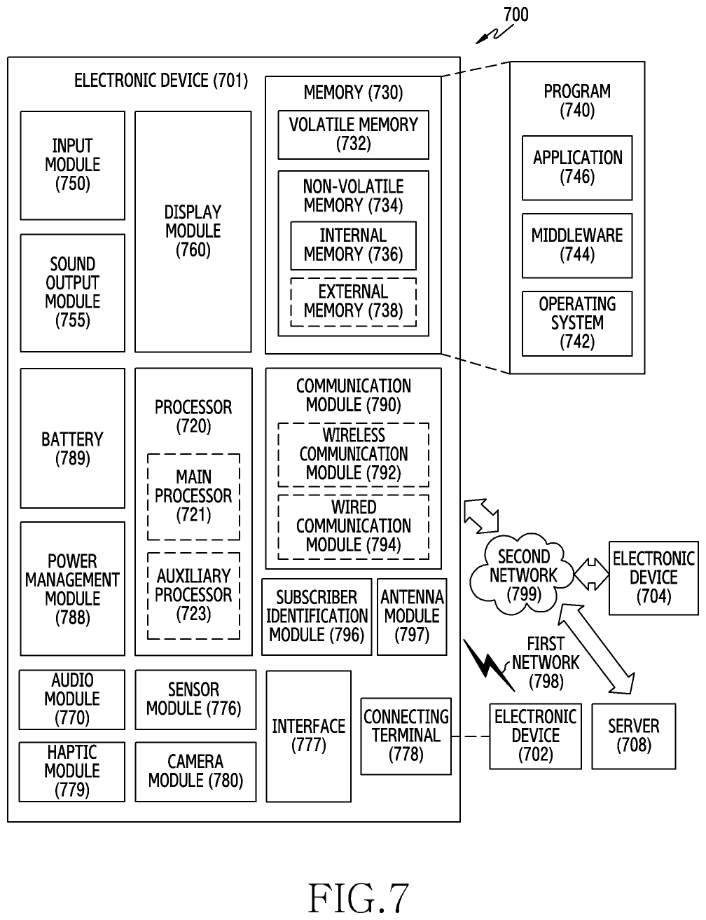

The case device 101 of FIG. 1A may correspond to an electronic device 701 of FIG. 7 described later. For example, the case device 101 may include some or all of the components constituting the electronic device 701 of FIG. 7.

Referring to FIG. 1A, in an embodiment, the case device 101 may have a rectangular parallelepiped shape, or a rectangular parallelepiped shape with curved corners, and may include an internal space for stowing the wearable device 200. For example, the case device 101 may store the wearable device 200 in the internal space. It is understood that the illustrated case device 101 having the rectangular parallelepiped shape is merely an example, and is not intended to limit the disclosure to this example embodiment. For example, a shape of the case device 101 may not be limited to the illustrated example, and any fitting shape may be utilized to as the shape of the case device 101.

In an embodiment, the case device 101 may include a housing 110. In an example, the housing 110 may include a first housing 111 and a second housing 112. In an example, the first housing 111 and the second housing 112 may be rotatable relative to one another through a hinge module (not shown). For example, a user may rotate the second housing 112 in a first direction with respect to the first housing 111, and open the case device 101 so as to place the wearable device 200 into the internal space, and then rotate the second housing 112 in a second direction opposite to the first direction with respect to the first housing 111 to close the case device 101.

FIG. 1C is a rear view of the case device 101 according to an embodiment.

In an embodiment, the case device 101 may include a first opening 103 and a first interface 105.

In an embodiment, the case device 101 may include at least one first opening 103. For example, the case device 101 may include at least one first opening 103 in a rear surface of the first housing 111. It is understood that the illustration herein is merely an example, and is not intended to limit the disclosure. For example, the case device 101 may include at least one first opening 103 in an upper surface (e.g., +z direction) of the second housing 112, a right side surface (e.g., +x direction) of the first housing 111, and/or a left side surface (e.g., −x direction) of the first housing 111. In an example, the first opening 103 may be disposed to correspond to a position of a main heat source (e.g., an application processor, a PCB, and/or a display module) of the wearable device 200 when the wearable device 200 is accommodated. In another example, the first opening 103 may be disposed to correspond to the position of the heat source of the case device 101 to facilitate a dissipation of heat from the heat source of the case device 101.

In an embodiment, the case device 101 may be connected to an external power supply through the first interface 105. In an example, the first interface 105 may be an interface for connecting a universal serial bus (USB) and/or on-the-go (OTG) connector. In an example, the first interface 105 may include a USB connector (e.g., a USB type C connector). In an example, the first interface 105 may be connected to an external power source (a travel adapter (TA) or a battery pack).

In an example, the case device 101 may include an interface (not shown) for wireless charging. For example, the case device 101 may include a wireless charging coil. For example, the case device 101 may include a coil for wireless charging. In an example, the case device 101 may be electrically connected to an external power supply (e.g., a wireless charging pad) through an interface for wireless charging. In an embodiment, when the case device 101 includes an interface for wireless charging, the first interface 105 may be omitted.

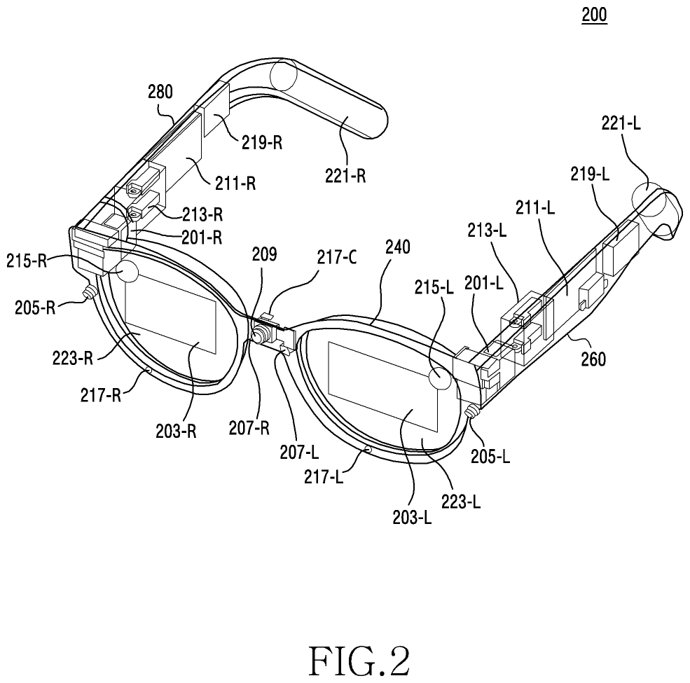

FIG. 2 is a diagram illustrating the wearable device 200 according to an embodiment.

The wearable device 200 of FIG. 2 may include some or all of components constituting the electronic device 701 of FIG. 7.

In an embodiment, the wearable device 200 may be stowed in the case device 101. For example, the wearable device 200 may be disposed in an internal space of a case device (e.g., the case device 101 of FIG. 1A) in a state in which the temples are folded via hinges 213-L and 213-R.

In an embodiment, the wearable device 200 may include a transparent member frame 240, a first leg portion 260, and a second leg portion 280 (e.g., the two temples). The first leg portion 260 and the second leg portion 280 may be rotatably connected to the transparent member frame 240 through the hinges 213-L and 213-R, respectively.

In an embodiment, the first leg portion 260 of the wearable device 200 may include a first light output module 201-L, the first hinge 213-L, a first printed circuit board (PCB) 211- L, a first speaker 219-L, and/or a first battery 221-L.

In an embodiment, the second leg portion 280 of the wearable device 200 may include a second light output module 201-R, the second hinge 213-R, a second PCB 211-R, a second speaker 219-R, and/or a second battery 221-R.

In an embodiment, the transparent member frame 240 of the wearable device 200 may include a first display 203-L, a second display 203-R, first cameras 205-L and 205-R, second cameras 207-L and 207-R, a third camera 209, a first optical member 215-L, a second optical member 215-R, a first transparent member 223-L, a second transparent member 223-R, and/or microphones 217-L, 217-R, and 217-C (center).

In an embodiment, “R” and “L” positioned at the end of identification signs described in FIG. 2 may mean components located at the right and left sides when worn. In an example, the construction located at the left side when the wearable device 200 is worn may be driven by power outputted from the first battery 221-L. The right side component may be driven by power outputted from the second battery 221-R.

Also, referring to FIG. 2, the components (e.g., the first PCB 211-L, the second PCB 211-R, the first speaker 219-L, the second speaker 219-R, the first battery 221-L, and the second battery 221-R) positioned in the first leg portion 260 or the second leg portion 280 are illustrated to be exposed to the external environment, but it is understood this is for convenience of description, and the components may be positioned inside the first leg portion 260 and/or the second leg portion 280 and not be exposed to the outside.

In an embodiment, the first light output module 201-L and the second light output module 201-R may be referred to as a light output module 201. The first display 203-L and the second display 203-R may be referred to as a display 203. The first PCB 211-L and the second PCB 211-R may be referred to as a PCB 211. The first optical member 215-L and the second optical member 215-R may be referred to as an optical member 215. The first battery 221-L and the second battery 221-R may be referred to as a battery 221. The first transparent member 223-L and the second transparent member 223-R may be referred to as a transparent member 223. In an embodiment, the transparent member 223 may include the display 203 and the optical member 215.

In an embodiment, the wearable device 200 may be a wearable electronic device. For example, the wearable device 200 may be a wearable electronic device of a glasses form (e.g., an augmented reality (AR) glass, a smart glass, or a head mounted device). However, this is merely an example, and the present disclosure is not limited thereto.

The wearable device 200 of the glasses form may operate while worn on a user's face. The transparent member 223 may be a plastic plate or a polymer material in which an external environment remains visible to a user, even in a state in which the wearable device 200 is worn on the user's face. In an example, the first transparent member 223-15 L may be disposed to face a user's left eye, and the second transparent member 223-R may be disposed to face a user's right eye.

In an embodiment, the wearable device 200 may acquire an image of the real world through the third camera 209, and receive an augmented real (AR) object related to a position of the acquired image or an object (e.g., a thing or a building) included in the acquired image, from another electronic device (e.g., a smart phone, a computer, a tablet PC, or a server) and present the same to the user through the light output module 201, the optical member 215, and the display 203.

In an embodiment, to recognize a current scene or environment viewed through the transparent member 223 of the wearable device 200, the wearable device 200 may utilize the first cameras 205-L and 205-R, the second cameras 207-L and 207-R, and the third camera 209.

In an embodiment, the wearable device 200 may receive an audio signal through the microphones 217-L, 217-R, and 217-C, and output an audio signal through the speakers 219-L and 219-R.

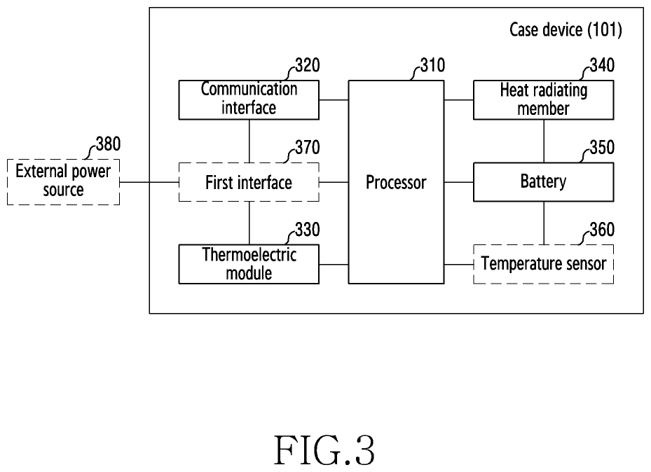

FIG. 3 is a block diagram illustrating component elements of the case device 101 according to an embodiment.

In an embodiment, the case device 101 may include a processor 310, a communication interface 320, a thermoelectric module 330, a heat radiating member 340, and/or a battery 350. In an example, the component elements of the case device 101 shown in FIG. 3 may be replaced with other component elements, or additional component elements may be included in the case device 101. For example, the case device 101 may further include a temperature sensor 360 and/or a first interface 370 (e.g., the first interface 105 of FIG. 1A).

In an embodiment, the processor 310 may correspond to a processor 720 of FIG. 7. The processor 310 may execute one or more instructions stored in a memory (not shown) and control operations of the component elements (e.g., the communication interface 320 and/or the thermoelectric module 330) of the case device 101. The processor 310 may execute an instruction included in software and control at least one other component elements connected to the processor 310. The processor 310 may acquire instructions, and interpret the acquired instructions to process data or perform computation. It may be understood that the operation of the case device 101 mentioned in the present disclosure is performed by the processor 310 executing the instruction.

In an embodiment, the communication interface 320 may perform communication with the wearable device 200. For example, the communication interface 320 may communicate with the wearable device 200 or a server through wireless communication or wired communication. In an example, the communication interface 320 may communicate and connect with the wearable device 200 may include communicating via a third device (e.g., a relay, a hub, an access point (AP), a server, or a gateway). For example, the wireless communication may include cellular communication that uses at least one of LTE, LTE Advance (LTE-A), code division multiple access (CDMA), wideband CDMA (WCDMA), universal mobile telecommunications system (UMTS), wireless broadband (WiBro), or global system for mobile communications (GSM). According to an embodiment, wireless communication, for example, may include at least one of wireless fidelity (Wi-Fi), Bluetooth, Bluetooth low energy (BLE), Zigbee, near field communication (NFC), magnetic secure transmission, radio frequency (RF), or a body area network (BAN). For example, the wired communication may include at least one of a universal serial bus (USB), a high definition multimedia interface (HDMI), recommended standard 232 (RS-232), power line communication, or a plain old telephone service (POTS). A network in which the wireless communication or the wired communication is performed may include at least one of a telecommunication network, for example, a computer network (e.g., LAN or WAN), the Internet, or a telephone network.

In an embodiment, the communication interface 320 may transmit data to the wearable device 200 or receive data from the wearable device 200. For example, the communication interface 320 may receive state information of the wearable device 200 from the wearable device 200.

In an embodiment, the case device 101 may include at least one thermoelectric module 330. The thermoelectric module 330 may be implemented in the form of a module in which N and P type thermo couples are connected to be electrically in series and thermally in parallel. For example, the thermoelectric module 330 may realize heat absorption and heat generation using the Peltier effect, and when a voltage is applied to the thermoelectric module 330, a heat absorption phenomenon may occur on the one surface thereof, and a heat generation phenomenon may occur on another surface, according to the direction of a current. In an embodiment, the thermoelectric module 330 may be electrically connected to the first interface 370 and receive power from an external power supply 380, or may be electrically connected to the battery 350 and receive power from the battery 350. In an example, the case device 101 may control an intensity of a current supplied to the thermoelectric module 330, to adjust an amount of heat. In an example, the thermoelectric module 330 may include a Peltier element.

In an embodiment, the case device 101 may adjust power (e.g., watts [W]) supplied to the thermoelectric module 330 through the processor 310, thereby controlling a temperature of an external device (e.g., the wearable device 200 of FIG. 2) accommodated in the case device 101.

In an embodiment, the case device 101 may include the heat radiating member 340. In an example, the heat radiating member 340 may uniformly diffuse, over the entire surface, heat provided from an internal component (e.g., the thermoelectric module 330, the battery 350, and/or a PCB (not shown)) of the case device 101, to improve heat radiating performance.

In an example, the heat radiating member 340 may include a member having excellent thermal conductivity or at least one or a combination of two or more of a heat pipe, a vapor chamber, or a graphite sheet.

In an embodiment, the battery 350 may supply power to at least one component element of the case device 101, and may include a battery cell, a battery module, or a battery pack. The battery 350 may include a capacitor or a secondary battery that stores power by charging. The battery 350 may be any one of a lithium ion battery (Li-ion), a lithium ion polymer battery (Li-ion polymer), a lead storage battery, a nickel-cadmium battery (NiCd), and a nickel hydrogen storage battery (NiMH). When a magnitude of a current supplied to the battery 350 is greater than a magnitude of a current outputted from the battery 350, the battery 350 may be charged. When the magnitude of the current outputted from the battery 350 is greater than the magnitude of the current supplied to the battery 350, the battery 350 may be discharged.

In an embodiment, the state information of the battery 350 may include a state of charge (SoC) of the battery 350, a battery capacity, or a combination thereof. For example, the SoC may indicate a degree of energy stored in the battery 350 and may be expressed as a value between 0 and 100% by using a percentage (%) unit. For example, 0% may correspond to a fully discharged state, and 100% may correspond to a fully charged state. The processor 310 may estimate or measure the SoC, based on various techniques. For example, the processor 310 may determine the SoC, based on voltages of positive and negative electrodes of the battery 350 or an open circuit voltage (OCV) of the battery 350.

In an embodiment, the case device 101 may receive power from the external power supply 380 via the first interface 370. In an example, the processor 310 may receive power from the external power supply 380 (e.g., TA, USB, power supply, or wireless charging device) by using the first interface 370. By using the power supplied from the external power supply 380, the processor 310 may charge the battery 350 of the case device 101 and/or the wearable device 200 stowed within the case device 101.

In an embodiment, the temperature sensor 360 may measure a temperature of the wearable device 200 accommodated in the case device 101. In an example, a plurality of temperature sensors 360 may be disposed inside the case device 101. In an example, the temperature sensor 360 may be included in the thermoelectric module 330, or be disposed around the thermoelectric module 330. In an example, the case device 101 may measure the temperature of the wearable device 200 accommodated in the case device 101 through the temperature sensor 360.

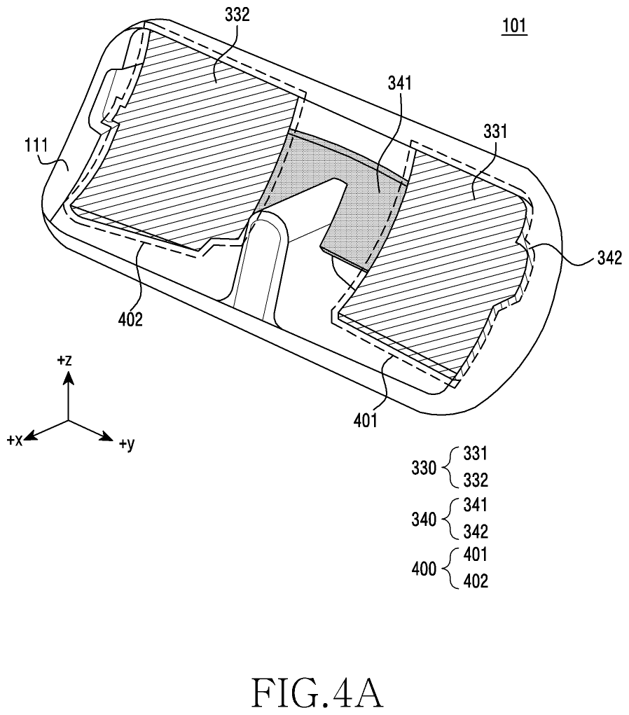

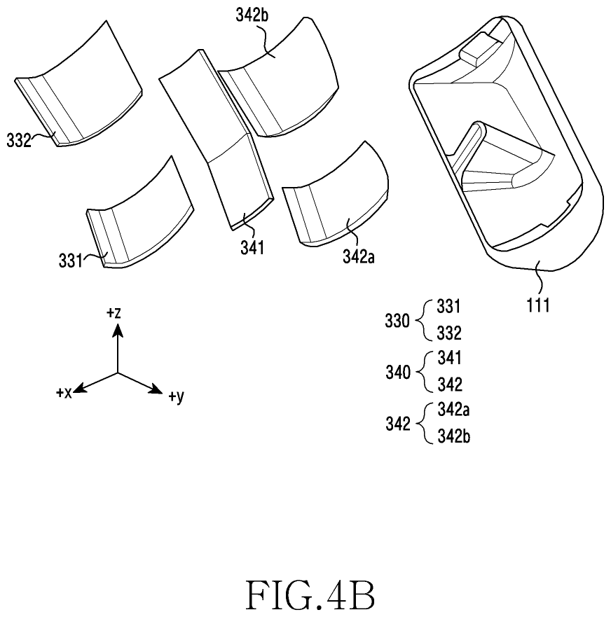

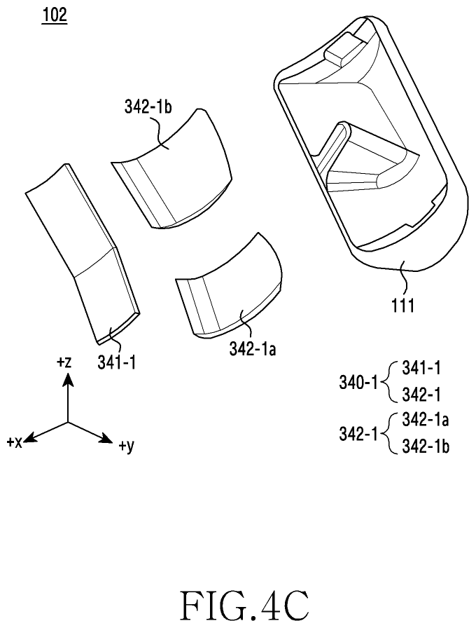

FIG. 4A is a perspective diagram illustrating an arrangement of the thermoelectric module 330 and the heat radiating member 340 within the case device 101, according to an embodiment.

In an embodiment, the case device 101 may include the thermoelectric module 330 and the heat radiating member 340. In an example, the thermoelectric module 330 may include a first thermoelectric module 331 and/or a second thermoelectric module 332.

In an embodiment, the case device 101 may include an accommodating groove 400 formed on an interior surface (e.g., and thus accessible from the internal space) of the case device 101 in which the wearable device 200 is accommodated. In an example, the accommodating groove 400 may include a passage for accommodating the wearable device 200 and dissipating a heat provided from a heat source of the wearable device 200. In an example, the heat source of the wearable device 200 may include at least one of a first PCB (e.g., the first PCB 211-L of FIG. 2) disposed in the first leg portion (e.g., the first leg portion 260 of FIG. 2) or a second PCB (e.g., the second PCB 211-R of FIG. 2) disposed in the second leg portion (e.g., the second leg portion 280 of FIG. 2). In an example, when the wearable device 200 is accommodated in the case device 101, the accommodating groove 400 of the case device 101 may be formed in a position so as to be adjacent to the heat source of the wearable device 200.

In an embodiment, a first accommodating groove 401 of the case device 101 may be disposed in a position adjacent to a first heat source of the wearable device 200. In an example, the first accommodating groove 401 may include a hole connecting the interior and the exterior of the case device 101. In an example, at least a part of the first thermoelectric module 331 may be disposed in a region corresponding to the first accommodating groove 401. In an example, the first thermoelectric module 331 may be disposed in one region of the case device 101 corresponding to a region corresponding to the left when the wearable device 200 is worn.

In an embodiment, a second accommodating groove 402 of the case device 101 may be disposed in a position adjacent to a second heat source of the wearable device 200. In an example, the second accommodating groove 402 may include a hole connecting the interior and the exterior of the case device 101. At least a part of the second thermoelectric module 332 may be disposed in a region corresponding to the second accommodating groove 402. The second thermoelectric module 332 may be disposed in one region of the case device 101 corresponding to a region corresponding to the right when the wearable device 200 is worn.

In an example, the first thermoelectric module 331 and second thermoelectric module 332 of the thermoelectric module 330 may be separated and disposed in the case device 101. In another example, the first thermoelectric module 331 and the second thermoelectric module 332 may be integrally formed and disposed in the case device 101.

In an embodiment, the thermoelectric module 330, when supplied with power, may include a first surface in which a heat absorption phenomenon occurs, and a second surface in which a heat generation phenomenon occurs. In an example, the first surface of the thermoelectric module 330 may be disposed to direct a main heat source (e.g., the first PCB 211-L and/or the second PCB 211-R of FIG. 2) of the wearable device 200 which is may be folded and stowed in an internal space of the case device 101. The thermoelectric module 330, when supplied with power, may absorb a heat provided from the main heat source of the wearable device 200.

In an embodiment, the case device 101 may include the heat radiating member 340. In an example, the heat radiating member 340 may be disposed in a rear surface (e.g., −x direction) of the thermoelectric module 330. In an example, the heat radiating member 340 may be disposed in a portion corresponding to the second surface of the thermoelectric module 330 in which the heat generation phenomenon occurs.

In an embodiment, the heat radiating member 340 may diffuse heat generated inside the case device 101 and a heat generated by the thermoelectric module 330 to another location, and/or radiate the same to the external environment of the case device 101.

In an embodiment, the heat radiating member 340 may include a first heat radiating member 341 and a second heat radiating member 342.

In an embodiment, the first heat radiating member 341 may be attached to or disposed on a rear surface (e.g., −x direction) of the thermoelectric module 330. In an example, the first heat radiating member 341 may include a heat pipe. The first heat radiating member 341 may include a heat transfer member capable of transferring a large amount of heat to a relatively lower temperature region using a fluid having a high specific heat. In an example, the first heat radiating member 341 may transfer heat generated from the second surface of the thermoelectric module 330 to a another relatively lower temperature region, and distribute the heat to a region that is distal from a peripheral region of the first heat radiating member 341. For example, the first heat radiating member 341 may be a heat transfer path, a heat diffusion path, or a heat radiating path. In an example, the first heat radiating member 341 may be formed in a shape having an area capable of covering a heat generation surface of the thermoelectric module 330. The first heat radiating member 341 may be configured in various shapes. In an example, the first heat radiating member 341 may be formed integrally with the first housing 111.

In an embodiment, the second heat radiating member 342 may be attached to or disposed in the rear surface (e.g., −x direction) of the first heat radiating member 341. In an example, the second heat radiating member 342 may be a graphite sheet. The second heat radiating member 342 may dissipate a heat transferred from the first heat radiating member 341. For example, the second heat radiating member 342 may dissipate the heat transferred from the first heat radiating member 341 through the first opening 103 disposed in the first housing 111.

In an embodiment, a battery (not shown) (e.g., the battery 350 of FIG. 3) may supply power to at least one component element of the case device 101. In an example, the battery may be disposed in a bottom surface (e.g., −z direction) of the case device 101. In an example, at least a part of the battery may be disposed on substantially the same plane as a printed circuit board (not shown). The battery 350 may be integrally disposed inside the case device 101, and may be disposed detachably with the case device 101. In an example, the battery 350 and the printed circuit board (not shown) may be main heat sources of the case device 101. In an embodiment, a heat generated from the battery 350 and the printed circuit board (not shown) may be dissipated to the outside of the case device 101 through the heat radiating member 340.

FIG. 4B is an exploded view of the case device 101 including the thermoelectric module 330 according to an embodiment.

Referring to FIG. 4B, the case device 101 may include the thermoelectric module 330 and the heat radiating member 340. In an example, the thermoelectric module 330 and the heat radiating member 340 may be included within the first housing 111 of the case device 101.

In an embodiment, the thermoelectric module 330 may include the first thermoelectric module 331 and/or the second thermoelectric module 332. In an example, the first thermoelectric module 331 may be disposed in one region of the case device 101 to face a region corresponding to a left side, as perceived by the user, when the wearable device 200 is worn. The second thermoelectric module 332 may be disposed in one region of the case device 101 to face a region corresponding to the right side, as perceived by the user, when the wearable device 200 is worn.

In an embodiment, the heat radiating member 340 is a component for dissipating a heat capable of being provided during the operation of the thermoelectric module 330, and may be attached to the rear surface (e.g., −x direction) of the thermoelectric module 330 through an adhesive member (not shown). In an example, the heat radiating member 340 may include a composite sheet in which two or more sheets (the first heat radiating member 341 and/or the second heat radiating member 342) are laminated.

In an embodiment, the heat radiating member 340 may include the first heat radiating member 341 and the second heat radiating member 342. In an example, the first heat radiating member 341 may be attached to the rear surface (e.g., −x direction) of the thermoelectric module 330 through an adhesive member (not shown). In an example, the second heat radiating member 342 may be attached to the rear surface (e.g., −x direction) of the thermoelectric module 330 through an adhesive member (not shown). The second heat radiating member 342 may include a 2-1st heat radiating member 342a and a 2-2nd heat radiating member 342b. In an example, the 2-1st heat radiating member 342a may be disposed in a region corresponding to the first thermoelectric module 331. The 2-2nd heat radiating member 342b may be disposed in a region corresponding to the second thermoelectric module 332. In another example, the 2-1st heat radiating member 342a and the 2-2nd heat radiating member 342b may be integrally formed and disposed on the rear surface (e.g., −x direction) of the first heat radiating member 341.

FIG. 4C is an exploded view of a case device 102 including a heat radiating member 340-1 according to another embodiment.

Referring to FIG. 4C, the case device 102 may include the heat radiating member 340-1. Except that the thermoelectric module 330 is not disposed, other component elements of the case device 102 may be applied in the same manner as in the case device 101.

In an embodiment, the heat radiating member 340-1 may diffuse heat generated inside the case device 102 and a heat generated by the wearable device 200 to another location, or dissipate the same to the external environment of the case device 102.

In an embodiment, the heat radiating member 340-1 may include a first heat radiating member 341-1 and a second heat radiating member 342-1.

In an embodiment, the first heat radiating member 341-1 may be disposed in a portion corresponding to a region in which the wearable device 200, when folded, is stowed in the case device 102. In an example, the first heat radiating member 341-1 may include a heat pipe.

In an embodiment, the second heat radiating member 342-1 may be disposed on a rear surface (e.g., −x direction) of the first heat radiating member 341-1. In an example, the second heat radiating member 342-1 may include a graphite sheet. In an example, the second heat radiating member 342-1 may be attached to the rear surface of the first heat radiating member 341-1 through an adhesive member (not shown). The second heat radiating member 342-1 may include a 2-1st heat radiating member 342-1a and a 2-2nd heat radiating member 342-1b. In an example, the 2-1st heat radiating member 342-1a may be disposed so as to correspond to a region corresponding to the left side, as perceived by a user, when the wearable device 200 is worn. The 2-2nd heat radiating member 342-1b may be disposed so as to correspond to a region corresponding to the right side, as perceived by a user, when the wearable device 200 is worn.

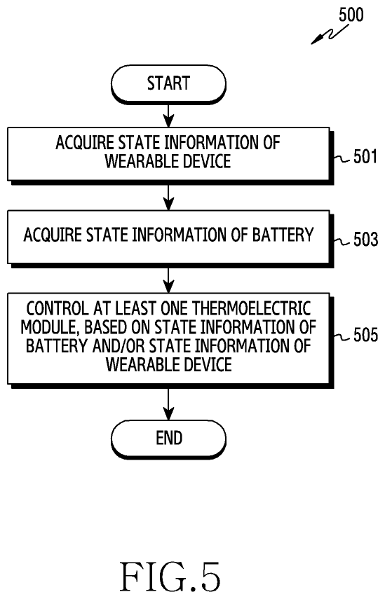

FIG. 5 is a flowchart 500 illustrating a method of limiting a temperature increase of the wearable device 200 through the case device 101 including the thermoelectric module 330 according to an embodiment.

In the following embodiment, each operation may be performed sequentially, but it is understood that the invention is not so limited as to necessarily perform the indicated steps sequentially. For example, the order of each operation may be changed, and/or two or more operations may be performed in parallel.

According to an embodiment, in operation 501, the case device 101 (e.g., the processor 310 of FIG. 3) may acquire state information of the wearable device 200. In an example, the state information of the wearable device 200 may include temperature information of the wearable device 200.

In an embodiment, the processor 310 may acquire the state information of the wearable device 200 directly from the wearable device 200, based on electrical connection of the wearable device 200 to the communication interface 320. The wearable device 200 may thus transmit the state information of the wearable device 200 to the case device 101. The case device 101 may receive the state information of the wearable device 200 through the communication interface 320. In an example, the case device 101 may perform power line communication (PLC) with the wearable device 200 through the communication interface 320.

In an embodiment, the case device 101 may include an opening/closing detection sensor (e.g., a Hall sensor) that monitors the opening or closing of the case device 101. In an example, when the second housing 112 of the case device 101 is rotated in a first direction with respect to the first housing 111, the processor 310 may detect the opening of the case device 101 through the opening/closing detection sensor. When the second housing 112 of the case device 101 is rotated in a second direction opposite to the first direction with respect to the first housing 111, the processor 310 may detect the closing of the case device 101 through the opening/closing detection sensor. In an example, the case device 101 may detect the mounting of the wearable device 200 in the internal space of the case device 101.

In an embodiment, the processor 310 may detect the wearable device 200 mounted in the internal space of the case device 101 and, when detecting the closing of the case device 101, the processor 310 may charge the wearable device 200 connected through an interface (e.g., the communication interface 320 or a pogo pin (not shown)). For example, the processor 310 may detect the wearable device 200 through the communication interface 320 and, when the wearable device 200 is detected in the internal space of the case device 101 and the processor 310 detects the closing of the case device 101, the processor 310 may initiate charging of the wearable device 200 as connected through the interface (e.g., the communication interface 320 or the pogo pin (not shown)).

In another embodiment, the processor 310 may acquire state information of the wearable device 200 through a sensor (e.g., the temperature sensor 360 of FIG. 3 and/or a sensor module 776 of FIG. 7) included in the case device 101. The processor 310 may detect that the wearable device 200 is stowed in the case device 101 through the sensor. In response to detecting stowage of the wearable device 200, the processor 310 may initiate measuring of a temperature of the wearable device 200 through a temperature sensor (e.g., the temperature sensor 360 of FIG. 3). The processor 310 may acquire temperature information of the wearable device 200 through the temperature sensor 360. In an example, the temperature information of the wearable device 200 may correspond to a temperature of a main heat source (e.g., the first PCB 211-L and/or the second PCB 211-R of FIG. 2) of the wearable device 200.

In an embodiment, the temperature information of the wearable device 200 may include temperature information of the first PCB 211-L of the wearable device 200 and/or temperature information of the second PCB 211-R of the wearable device 200. In an example, the temperature information of the wearable device 200 may include temperature information of the first optical output module 201-L and/or temperature information of the second optical output module 201-R of the wearable device 200. In an example, the temperature information of the wearable device 200 may include temperature information of a camera (e.g., the first cameras 205-L and 205-R of FIG. 2, the second cameras 207-L and 207-R, or the third camera 209) disposed in a transparent member frame (e.g., the transparent member frame 240 of FIG. 2) of the wearable device 200.

According to an embodiment, in operation 503, the case device 101 (e.g., the processor 310 of FIG. 3) may acquire state information of a battery (e.g., the battery 350 of FIG. 3). In an example, the state information of the battery 350 may include information on a remaining amount of the battery 350 or information on a state of charge (SoC) of the battery 350.

In an embodiment, the order of operation 501 and operation 503 is not limited to the order illustrated in the flowchart 500, and may be performed simultaneously or be performed in a reverse order to the order illustrated in the flowchart 500 according to an embodiment.

According to an embodiment, in operation 505, the case device 101 (e.g., the processor 310 of FIG. 3) may control at least one thermoelectric module (e.g., the thermoelectric module 330 of FIG. 3), based on at least one of the state information of the battery 350 and the state information of the wearable device 200.

In an embodiment, the processor 310 may control at least one thermoelectric module 330 such that a temperature of the wearable device 200 may be maintained within a specified temperature range, based on at least one of the state information of the battery 350 and the state information of the wearable device 200. Controlling the at least one thermoelectric module 330 may include an operation of adjusting a level of power (e.g., current and/or voltage) and/or an operation of cutting off the power. The specified temperature range may be a temperature range in which the components of the wearable device 200 can function normally without risk of operational failure or a lifespan reduction of the components of the wearable device 200. The specified temperature range may vary according to a lifespan state and/or a function of the components of the wearable device 200.

In an embodiment, the processor 310 may control the thermoelectric module 330, based on the temperature information of the wearable device 200 included in the state information of the wearable device 200. For example, when a temperature of the wearable device 200 corresponds to a first temperature and the first temperature exceeds the specified temperature range, the processor 310 may supply a first voltage to the thermoelectric module 330. The processor 310 may supply the first voltage to the thermoelectric module 330 and decrease the temperature of the wearable device 200 through one portion of the thermoelectric module 330 in which heat absorption occurs. In an example, when the temperature of the wearable device 200 corresponds to a second temperature higher than the first temperature, the processor 310 may supply a second voltage higher than the first voltage to the thermoelectric module 330. The processor 310 may supply the second voltage to the thermoelectric module 330 and relatively more quickly decrease the temperature of the wearable device 200 than when supplying the first voltage through one portion of the thermoelectric module 330 in which the heat absorption phenomenon occurs.

In an embodiment, when the temperature of the wearable device 200 corresponds to a third temperature lower than the first temperature, the processor 310 may not supply a voltage to the thermoelectric module 330 or may supply a third voltage lower than the first voltage.

In an embodiment, the processor 310 may control the thermoelectric module 330, based on the state information of the battery 350 and the state information of the wearable device 200.

Table 1 is a table showing power data supplied to the thermoelectric module 330 according to the state information of the battery 350 and the temperature information of the wearable device 200 in an embodiment.

TABLE 1

| | | | | | State of charge | | | | | |
|---|---|---|---|---|---|---|---|---|---|---|
| | | State of charge | | | of battery 350 | | | State of charge | | |
| State of charge | | of battery 350 | | | (more than 10% | | | of battery 350 | | |
| of battery 350 | | (more than 30%) | | | and less than 30%) | | | (less than 10%) | | |
| | Temp. of | Operation of | | | Operation of | | | Operation of | | |
| | wearable | thermoelectric | | | thermoelectric | | | thermoelectric | | |
| | device | module 330 | | | module 330 | | | module 330 | | |
| | 200 | Voltage | Current | Power | Voltage | Current | Power | Voltage | Current | Power |
| step | [unit: ° C.] | [V] | [A] | [W] | [V] | [ A] | [W] | [V] | [A] | [W] |
| 1 | 47 | 2.5 | 0.27 | 0.675 | 2.2 | 0.23 | 0.506 | 2.0 | 0.2 | 0.4 |
| 2 | 44 | 2.0 | 0.2 | 0.4 | 1.8 | 0.18 | 0.324 | 1.5 | 0.16 | 0.24 |
| 3 | 41 | 1.5 | 0.16 | 0.24 | 1.5 | 0.16 | 0.24 | 1.0 | 0.1 | 0.1 |
| 4 | 38 | 1.0 | 0.1 | 0.1 | 1.0 | 0.1 | 0.1 | — | — | — |
| 5 | 34 | — | — | — | — | — | — | — | — | — |

Referring to Table 1, when the temperature of the wearable device 200 corresponds to about 47° C., and the state of charge of the battery 350 corresponds to about 30% or more, the processor 310 may supply an electrical energy of about 0.675 W (e.g., a voltage may be about 2.5V, and a current may be about 0.27 A) to the thermoelectric module 330. When the temperature of the wearable device 200 corresponds to about 47° C., and the state of charge of the battery 350 corresponds to about 10% or more and less than 30%, the processor 310 may supply an electrical energy of about 0.506 W (e.g., the voltage may be about 2.2V, and the current may be about 0.23 A). In an example, even if the temperature information of the wearable device 200 is substantially the same, the processor 310 may control the electrical energy supplied to the thermoelectric module 330 according to information on the state of charge of the battery 350.

Referring to Table 1,when the state of charge of the battery 350 corresponds to about 10% or more and less than 30%, and the temperature of the wearable device 200 corresponds to about 44° C., the processor 310 may supply an electrical energy of about 0.324 W (e.g., the voltage may be about 1.8V, and the current may be about 0.18 A) to the thermoelectric module 330. When the state of charge of the battery 350 corresponds to about 10% or more and less than 30%, and the temperature of the wearable device 200 corresponds to about 41° C., the processor 310 may supply an electrical energy of about 0.24 W (e.g., the voltage may be about 1.5V and the current may be about 0.16 A) to the thermoelectric module 330. In an example, even though the information on the state of charge of the battery 350 is substantially the same, the processor 310 may control the electrical energy supplied to the thermoelectric module 330 according to the temperature information of the wearable device 200.

Referring to Table 1, when the specified temperature range corresponds to about 34° C. or less with respect to the temperature of the wearable device 200, the processor 310 may limit the electrical energy supplied to the thermoelectric module 330, when the temperature of the wearable device 200 is within the specified temperature range.

In an embodiment, when the temperature of the wearable device 200 exceeds the specified temperature range, and the state of charge of the battery 350 is less than a specified percentage (e.g., about 10%), the processor 310 may limit the electrical energy supplied to the thermoelectric module 330. When the state of charge of the battery 350 is less than the specified percentage, the processor 310 may limit the electrical energy supplied to the thermoelectric module 330 in which it may operate normally through the components of the case device 101 other than the thermoelectric module 330.

In an embodiment, when the state of charge of the battery 350 is less than a specified percentage, the processor 310 may charge the battery 350 by using power supplied from an external power source of the processor 310. In an example, when the state of charge of the battery 350 is less than the specified percentage, the processor 310 may rapidly charge the battery 350 through the external power source supporting fast charging. When the case device 101 charges the battery 350 through the external power source supporting the fast charging, an amount of generated heat may be relatively higher than when the battery 350 is charged through an external power source supporting normal charging.

In an embodiment, the processor 310 may simultaneously or sequentially perform an operation of charging the battery 350 and an operation of controlling the thermoelectric module 330. In an example, the processor 310 may perform an operation of controlling the thermoelectric module 330 in order to discharge a heat generated through the charging of the battery 350 in response to the operation of charging the battery 350. In another example, the processor 310 may simultaneously perform an operation of charging the battery 350 and an operation of controlling the thermoelectric module 330 for a first time, and after the first time, the processor 310 may perform only the operation of charging the battery 350.

In an embodiment, while the processor 310 controls the thermoelectric module 330, the processor 310 may periodically or continuously acquire state information of the wearable device 200.

In an embodiment, when the temperature information of the wearable device 200 includes temperature information on a first heat source (e.g., the first PCB 211-L of FIG. 2) of the wearable device 200 and temperature information on a second heat source (e.g., the second PCB 211-R of FIG. 2) of the wearable device 200, the processor 310 may control the first thermoelectric module (e.g., the first thermoelectric module 331 of FIG. 4A), based on the temperature information on the first heat source of the wearable device 200 and the state information of the battery 350. In an example, the first thermoelectric module 331 may be partially exposed through a region corresponding to the first accommodating groove 401 adjacent to the first heat source disposed inside the wearable device 200 accommodated in the case device 101. In an example, the first thermoelectric module 331 supplied with power through the processor 310 may decrease a temperature of a heat provided from the first heat source through a portion of the first thermoelectric module 331 which is exposed through the first accommodating groove (to be described later) and in which the heat absorption phenomenon occurs.

In an embodiment, the processor 310 may control a second thermoelectric module (e.g., the second thermoelectric module 332 of FIG. 4A), based on the temperature information on the second heat source and the state information of the battery 350. In an example, the second thermoelectric module (to be described later) may be partially exposed through a region corresponding to the second accommodating groove 402 adjacent to the second heat source disposed inside the wearable device 200 accommodated in the case device 101. The second thermoelectric module 332 supplied with power through the processor 310 may decrease a temperature of a heat provided from the second heat source through a portion of the second thermoelectric module 332 which is exposed through the second accommodating groove 402 and in which the heat absorption phenomenon occurs.

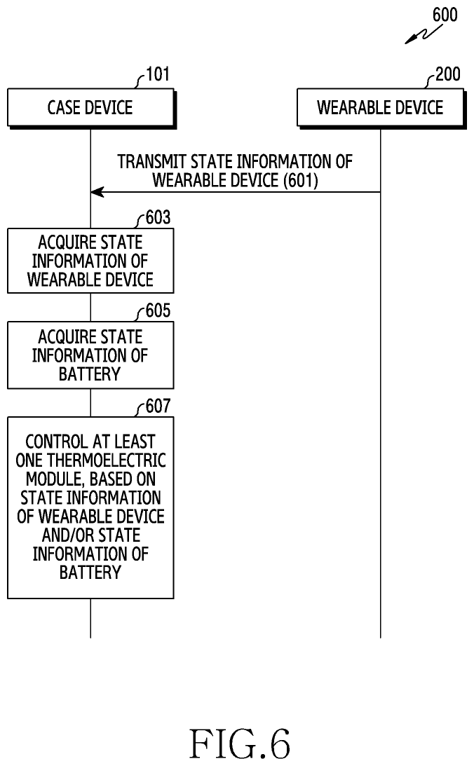

FIG. 6 is an operation flowchart 600 illustrating a method of limiting a temperature rise of the wearable device 200 through the case device 101 including the thermoelectric module 330 according to an embodiment.

According to an embodiment, in operation 601, the wearable device 200 may transmit state information of the wearable device 200 to the case device 101. In an example, the state information of the wearable device 200 may include temperature information of the wearable device 200. In an example, the wearable device 200 may measure a temperature of the wearable device 200 through the temperature sensor 360 disposed in the wearable device 200. In an embodiment, in response to a request of the case device 101 for transmitting the state information of the wearable device 200, the wearable device 200 may measure the temperature of the wearable device 200 through the temperature sensor 360 disposed in the wearable device 200. In an example, the case device 101 may request the wearable device 200 to transmit the state information of the wearable device 200. In an example, the case device 101 may periodically request transmission of the state information of the wearable device 200. In another example, when the processor 310 detects stowage of the wearable device 200 in an internal space of the case device 101, the processor 310 may request the wearable device 200 to transmit the state information of the wearable device 200. In another example, the processor 310 may detect stowage of the wearable device 200 in the internal space of the case device 101, and when detecting the closing of the case device 101, the processor 310 may request transmission of the state information of the wearable device 200 from the wearable device 200. In an embodiment, the wearable device 200 may measure temperatures of the first PCB 211-L and the second PCB 211-R through each temperature sensor (e.g., the temperature sensor 360) disposed in a first heat source (e.g., the first PCB 211-L of FIG. 2) and a second heat source (e.g., the second PCB 211-R of FIG. 2) of the wearable device 200. The wearable device 200 may transmit temperature information on the first PCB 211-L and the second PCB 211-R to the case device 101. Although the embodiment has been described in which the heat source of the wearable device 200 corresponds to the PCB 211, the present disclosure is not limited thereto. For example, the heat source of the wearable device may correspond to an optical output module (e.g., the optical output module 201 of FIG. 2) or a display (e.g., the display 203 of FIG. 2) disposed in the wearable device 200. In an embodiment, operation 601 may be omitted. For example, the processor 310 may acquire the state information of the wearable device 200 through the sensor (e.g., the temperature sensor 360 of FIG. 3 and/or the sensor module 776 of FIG. 7) disposed in the case device 101. The processor 310 may obtain the wearable device 200 accommodated in the case device 101 through the sensor, and measure the temperature of the wearable device 200 through the temperature sensor 360.

According to an embodiment, in operation 603, the case device 101 (e.g., the processor 310 of FIG. 3) may acquire the state information of the wearable device 200. In an example, in operation 601, the wearable device 200 may transmit the state information of the wearable device 200 to the case device 101. The processor 310 may receive the state information of the wearable device 200 from the wearable device 200 through a communication interface (e.g., the communication interface 320 of FIG. 3). For example, the state information of the wearable device 200 may include temperature information, battery information, and/or operation state (e.g., running application) information of the wearable device 200.

According to an embodiment, in operation 605, the case device 101 (e.g., the processor 310 of FIG. 3) may acquire the state information of the battery 350. In an embodiment, the state information of the battery 350 may include information about a state of charge of the battery 350. The state of charge of the battery 350 may mean a level of energy stored in the battery 350 and may be expressed in percentage (%) units. In an example, the state information of the battery 350 may include information about an expected use time of the case device 101. The information on the expected use time of the case device 101 may mean a time until the battery 350 is fully discharged according to the state of charge of the battery 350, and may be expressed in minute or hour units.

According to an embodiment, in operation 607, the case device 101 (e.g., the processor 310 of FIG. 3) may control at least one thermoelectric module (e.g., the thermoelectric module 330 of FIG. 3), based on at least one of the state information of the wearable device 200 and the state information of the battery 350. In an example, the at least one thermoelectric module 330 may be disposed to be partially exposed through a region corresponding to the first accommodating groove 401 and a region corresponding to the second accommodating groove 402 of the case device 101. In an example, the processor 310 may determine a characteristic of power that will be supplied to the thermoelectric module 330, based on at least one of the state information of the wearable device 200 and the state information of the battery 350, and supply the power to the thermoelectric module 330 using the determined characteristic. In an example, when the thermoelectric module 330 is supplied with power through the processor 310, this may limit an increase in temperature of the stowed wearable device 200 via at least a portion of the thermoelectric module 330 which is exposed to an external environment through the accommodating groove, and in which the heat absorption phenomenon occurs.

FIG. 7 is a block diagram of an electronic device 701 in a network environment 700 according to various embodiments. For example, the electronic device 701 may correspond to the case device 101 or the wearable device 200, and may correspond to the component elements shown in FIG. 3.

Referring to FIG. 7, the electronic device 701 in the network environment 700 may communicate with an electronic device 702 via a first network 798 (e.g., a short-range wireless communication network), or at least one of an electronic device 704 or a server 708 via a second network 799 (e.g., a long-range wireless communication network). According to an embodiment, the electronic device 701 may communicate with the electronic device 704 via the server 708. According to an embodiment, the electronic device 701 may include a processor 720 (e.g., the processor 310), memory 730, an input module 750, a sound output module 755, a display module 760, an audio module 770, a sensor module 776 (e.g., the temperature sensor 360), an interface 777 (e.g., the first interface 370), a connecting terminal 778, a haptic module 779, a camera module 780, a power management module 788, a battery 789 (e.g., the battery 350), a communication module 790 (e.g., the communication interface 320), a subscriber identification module(SIM) 796, or an antenna module 797. In some embodiments, at least one of the components (e.g., the connecting terminal 778) may be omitted from the electronic device 701, or one or more other components may be added in the electronic device 701. In some embodiments, some of the components (e.g., the sensor module 776, the camera module 780, or the antenna module 797) may be implemented as a single component (e.g., the display module 760).

The processor 720 may execute, for example, software (e.g., a program 740) to control at least one other component (e.g., a hardware or software component) of the electronic device 701 coupled with the processor 720, and may perform various data processing or computation. According to an embodiment, as at least part of the data processing or computation, the processor 720 may store a command or data received from another component (e.g., the sensor module 776 or the communication module 790) in volatile memory 732, process the command or the data stored in the volatile memory 732, and store resulting data in non-volatile memory 734. According to an embodiment, the processor 720 may include a main processor 721 (e.g., a central processing unit (CPU) or an application processor (AP)), or an auxiliary processor 723 (e.g., a graphics processing unit (GPU), a neural processing unit (NPU), an image signal processor (ISP), a sensor hub processor, or a communication processor (CP)) that is operable independently from, or in conjunction with, the main processor 721. For example, when the electronic device 701 includes the main processor 721 and the auxiliary processor 723, the auxiliary processor 723 may be adapted to consume less power than the main processor 721, or to be specific to a specified function. The auxiliary processor 723 may be implemented as separate from, or as part of the main processor 721.

The auxiliary processor 723 may control at least some of functions or states related to at least one component (e.g., the display module 760, the sensor module 776, or the communication module 790) among the components of the electronic device 701, instead of the main processor 721 while the main processor 721 is in an inactive (e.g., sleep) state, or together with the main processor 721 while the main processor 721 is in an active state (e.g., executing an application). According to an embodiment, the auxiliary processor 723 (e.g., an image signal processor or a communication processor) may be implemented as part of another component (e.g., the camera module 780 or the communication module 790) functionally related to the auxiliary processor 723. According to an embodiment, the auxiliary processor 723 (e.g., the neural processing unit) may include a hardware structure specified for artificial intelligence model processing. An artificial intelligence model may be generated by machine learning. Such learning may be performed, e.g., by the electronic device 701 where the artificial intelligence is performed or via a separate server (e.g., the server 708). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 730 may store various data used by at least one component (e.g., the processor 720 or the sensor module 776) of the electronic device 701. The various data may include, for example, software (e.g., the program 740) and input data or output data for a command related thererto. The memory 730 may include the volatile memory 732 or the non-volatile memory 734.

The program 740 may be stored in the memory 730 as software, and may include, for example, an operating system (OS) 742, middleware 744, or an application 746.

The input module 750 may receive a command or data to be used by another component (e.g., the processor 720) of the electronic device 701, from the outside (e.g., a user) of the electronic device 701. The input module 750 may include, for example, a microphone, a mouse, a keyboard, a key (e.g., a button), or a digital pen (e.g., a stylus pen).

The sound output module 755 may output sound signals to the outside of the electronic device 701. The sound output module 755 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 760 may visually provide information to the outside (e.g., a user) of the electronic device 701. The display module 760 may include, for example, a display, a hologram device, or a projector and control circuitry to control a corresponding one of the display, hologram device, and projector. According to an embodiment, the display module 760 may include a touch sensor adapted to detect a touch, or a pressure sensor adapted to measure the intensity of force incurred by the touch.

The audio module 770 may convert a sound into an electrical signal and vice versa. According to an embodiment, the audio module 770 may obtain the sound via the input module 750, or output the sound via the sound output module 755 or a headphone of an external electronic device (e.g., an electronic device 702) directly (e.g., wiredly) or wirelessly coupled with the electronic device 701.

The sensor module 776 may detect an operational state (e.g., power or temperature) of the electronic device 701 or an environmental state (e.g., a state of a user) external to the electronic device 701, and then generate an electrical signal or data value corresponding to the detected state. According to an embodiment, the sensor module 776 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 777 may support one or more specified protocols to be used for the electronic device 701 to be coupled with the external electronic device (e.g., the electronic device 702) directly (e.g., wiredly) or wirelessly. According to an embodiment, the interface 777 may include, for example, a high definition multimedia interface (HDMI), a universal serial bus (USB) interface, a secure digital (SD) card interface, or an audio interface.

A connecting terminal 778 may include a connector via which the electronic device 701 may be physically connected with the external electronic device (e.g., the electronic device 702). According to an embodiment, the connecting terminal 778 may include, for example, a HDMI connector, a USB connector, a SD card connector, or an audio connector (e.g., a headphone connector).

The haptic module 779 may convert an electrical signal into a mechanical stimulus (e.g., a vibration or a movement) or electrical stimulus which may be recognized by a user via his tactile sensation or kinesthetic sensation. According to an embodiment, the haptic module 779 may include, for example, a motor, a piezoelectric element, or an electric stimulator.

The camera module 780 may capture a still image or moving images. According to an embodiment, the camera module 780 may include one or more lenses, image sensors, image signal processors, or flashes.

The power management module 788 may manage power supplied to the electronic device 701. According to an embodiment, the power management module 788 may be implemented as at least part of, for example, a power management integrated circuit (PMIC).

The battery 789 may supply power to at least one component of the electronic device 701. According to an embodiment, the battery 789 may include, for example, a primary cell which is not rechargeable, a secondary cell which is rechargeable, or a fuel cell.

The communication module 790 may support establishing a direct (e.g., wired) communication channel or a wireless communication channel between the electronic device 701 and the external electronic device (e.g., the electronic device 702, the electronic device 704, or the server 708) and performing communication via the established communication channel. The communication module 790 may include one or more communication processors that are operable independently from the processor 720 (e.g., the application processor (AP)) and supports a direct (e.g., wired) communication or a wireless communication. According to an embodiment, the communication module 790 may include a wireless communication module 792 (e.g., a cellular communication module, a short-range wireless communication module, or a global navigation satellite system (GNSS) communication module) or a wired communication module 794 (e.g., a local area network (LAN) communication module or a power line communication (PLC) module). A corresponding one of these communication modules may communicate with the external electronic device via the first network 798 (e.g., a short-range communication network, such as Bluetooth™, wireless-fidelity (Wi-Fi) direct, or infrared data association (IrDA)) or the second network 799 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 792 may identify and authenticate the electronic device 701 in a communication network, such as the first network 798 or the second network 799, using subscriber information (e.g., international mobile subscriber identity (IMSI)) stored in the subscriber identification module 796.

The wireless communication module 792 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 792 may support a high-frequency band (e.g., the mmWave band) to achieve, e.g., a high data transmission rate. The wireless communication module 792 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 792 may support various requirements specified in the electronic device 701, an external electronic device (e.g., the electronic device 704), or a network system (e.g., the second network 799). According to an embodiment, the wireless communication module 792 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 797 may transmit or receive a signal or power to or from the outside (e.g., the external electronic device) of the electronic device 701. According to an embodiment, the antenna module 797 may include an antenna including a radiating element composed of a conductive material or a conductive pattern formed in or on a substrate (e.g., a printed circuit board (PCB)). According to an embodiment, the antenna module 797 may include a plurality of antennas (e.g., array antennas). In such a case, at least one antenna appropriate for a communication scheme used in the communication network, such as the first network 798 or the second network 799, may be selected, for example, by the communication module 790 (e.g., the wireless communication module 792) from the plurality of antennas. The signal or the power may then be transmitted or received between the communication module 790 and the external electronic device via the selected at least one antenna. According to an embodiment, another component (e.g., a radio frequency integrated circuit (RFIC)) other than the radiating element may be additionally formed as part of the antenna module 797.

According to various embodiments, the antenna module 797 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 701 and the external electronic device 704 via the server 708 coupled with the second network 799. Each of the electronic devices 702 or 704 may be a device of a same type as, or a different type, from the electronic device 701.

According to an embodiment, all or some of operations to be executed at the electronic device 701 may be executed at one or more of the external electronic devices 702, 704, or 708. For example, if the electronic device 701 should perform a function or a service automatically, or in response to a request from a user or another device, the electronic device 701, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 701. The electronic device 701 may provide the outcome, with or without further processing of the outcome, as at least part of a reply to the request. To that end, a cloud computing, distributed computing, mobile edge computing (MEC), or client-server computing technology may be used, for example. The electronic device 701 may provide ultra-low-latency services using, e.g., distributed computing or mobile edge computing. In another embodiment, the external electronic device 704 may include an internet-of-things (IoT) device. The server 708 may be an intelligent server using machine learning and/or a neural network. According to an embodiment, the external electronic device 704 or the server 708 may be included in the second network 799. The electronic device 701 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 740) including one or more instructions that are stored in a storage medium (e.g., internal memory 736 or external memory 738) that is readable by a machine (e.g., the electronic device 701). For example, a processor (e.g., the processor 720) of the machine (e.g., the electronic device 701) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

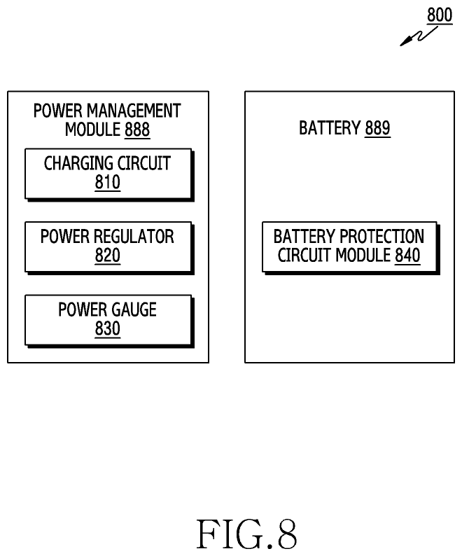

FIG. 8 is a block diagram 800 of a power management module 888 (e.g., the power management module 788 of FIG. 7) and a battery 889 (e.g., the battery 789 of FIG. 7) according to various embodiments.

Referring to FIG. 8, the power management module 888 may include a charging circuit 810, a power regulator 820, or a power gauge 830. The charging circuit 810 may charge the battery 889 using power supplied from an external power source for an electronic device (e.g., the electronic device 701 of FIG. 7). According to an embodiment, the charging circuit 810 may select a charging scheme (e.g., normal charging or fast charging), based on at least a part of the type (e.g., a power adapter, a USB or wireless charging) of the external power source, a magnitude (e.g., about 20 watts or more) of power suppliable from the external power source, or an attribute of the battery 889, and may charge the battery 889 using the selected charging scheme. The external power source may be wiredly connected to the electronic device 701, for example, through a connection terminal (e.g., the connection terminal 778 of FIG. 7), or may be wirelessly connected through an antenna module (e.g., the antenna module 797 of FIG. 7).

The power regulator 820 may provide a power at a plurality of different voltages or different current levels by, for example, adjusting a voltage level or a current level of power supplied from the external power source or the battery 889. The power regulator 820 may adjust the power of the external power source or the battery 889 to a voltage or current level suitable for each of some of the component elements included in the electronic device 701. According to an embodiment, the power regulator 820 may be implemented in the form of a low drop out (LDO) regulator or a switching regulator. The power gauge 830 may measure use state information on the battery 789 (e.g., a capacity of the battery 889, the number of times of charging and discharging, a voltage, or a temperature).

The power management module 888 may determine state of charge information (e.g., lifespan, overvoltage, undervoltage, overcurrent, overcharge, over-discharge, overheating, short circuit, or swelling) related to the charging of the battery 889, based at least in part on the measured use state information, by, for example, using the charging circuit 810, the voltage regulator 820, or the power gauge 830. The power management module 888 may determine whether the battery 889 is normal or abnormal, based at least in part on the determined state of charge information. When it is determined that a state of the battery 889 is abnormal, the power management module 888 may adjust the charging of the battery 889 (e.g., decrease a charging current or voltage, or stop charging). According to an embodiment, at least some of the functions of the power management module 888 may be performed by an external control device (e.g., the processor 720).

According to an embodiment, the battery 889 may include a battery protection circuit module (PCM) 840. The battery protection circuit module 840 may perform one or more of various functions (e.g., pre-blocking functions) for preventing a deterioration or damage of the battery 889. The battery protection circuit module 840 may, additionally or alternatively, be configured as at least a part of a battery management system (BMS) capable of performing various functions including cell balancing, battery capacity measurement, charge/discharge recursion measurement, temperature measurement, or voltage measurement.

According to an embodiment, at least a part of the use state information or charge state information of the battery 889 may be measured using a corresponding sensor (e.g., a temperature sensor) among the sensor module 776, the power gauge 830, or the power management module 888. According to an embodiment, the corresponding sensor (e.g., the temperature sensor) among the sensor module 776 may be included as a part of the battery protection circuit module 840, or be disposed adjacent to the battery 789 as a device separate from this.

A case device (e.g., the case device 101) for presenting a charging function of various embodiments may include a housing (e.g., the housing 110) including an internal space for accommodating a wearable device (e.g., the wearable device 200), a communication interface (e.g., the communication interface 320) for presenting a wired or wireless connection with the wearable device, at least one accommodating groove (e.g., the accommodating groove 400) formed in the internal space for accommodating the wearable device, at least one thermoelectric module (e.g., the thermoelectric module 300) disposed to be partially exposed through the at least one accommodating groove, a heat radiating member (e.g., the heat radiating member 340) disposed adjacent to the at least one thermoelectric module, a battery (e.g., the battery 350) disposed inside the housing, and at least one processor (e.g., the processor 310) electrically connected to the communication interface, the at least one thermoelectric module, the heat radiating member, and the battery. The at least one processor may acquire state information of the wearable device, and control the at least one thermoelectric module, based on the state information of the wearable device.

According to an embodiment, the state information of the wearable device may include temperature information of the wearable device.

According to an embodiment, the at least one processor may control the at least one thermoelectric module not to operate when the temperature information of the wearable device is equal to or less than a specified temperature.

According to an embodiment, the at least one processor may acquire state information of the wearable device from the wearable device electrically connected to the communication interface.

According to an embodiment, the case device may further include at least one temperature sensor 360, and the at least one processor may acquire the temperature information of the wearable device accommodated in the internal space through the at least one temperature sensor.

According to an embodiment, the at least one temperature sensor may be disposed around the at least one thermoelectric module.

According to an embodiment, the at least one processor may acquire battery state information of the case device, and control the at least one thermoelectric module, based on at least one of the state information of the wearable device and the battery state information of the case device.

According to an embodiment, the heat radiating member may include at least one of a graphite sheet, a vapor chamber, and a heat pipe.

According to an embodiment, the housing may include at least one first opening passing through at least one surface of the housing.

According to an embodiment, the state information of the wearable device may include temperature information of a first leg portion and a second leg portion of the wearable device.

According to an embodiment, the at least one accommodating groove may include a first accommodating groove formed in the internal space in which the first leg portion is accommodated, and a second accommodating groove formed in the internal space in which the second leg portion is accommodated.

According to an embodiment, the at least one thermoelectric module may include a first thermoelectric module disposed to be partially exposed through the first accommodating groove and a second thermoelectric module disposed to be partially exposed through the second accommodating groove, and the at least one processor may control the first thermoelectric module and the second thermoelectric module, based on the state information of the case device and/or temperature information of the first leg portion and the second leg portion of the wearable device.

According to an embodiment, the at least one thermoelectric module may include a Peltier element.

A case device (e.g., the case device 102) for presenting a charging function of various embodiments may include a housing (e.g., the housing 110) including an internal space for accommodating a wearable device (e.g., the wearable device 200), at least one accommodating groove formed in the internal space and accommodating the wearable device and dissipating a heat provided from the wearable device, and a heat radiating member (e.g., the heat radiating member 340) disposed in a position corresponding to the at least one accommodating groove and exposed at least partially.

According to an embodiment, the heat radiating member may include at least one of a graphite sheet, a vapor chamber, and a heat pipe.

A method for operating a case device (e.g., the case device 101) having at least one thermoelectric module (e.g., the thermoelectric module 330) of various embodiments may include acquiring state information of a wearable device (e.g., the wearable device 200) accommodated in the case device, and controlling the at least one thermoelectric module disposed adjacent to the wearable device, based on the state information of the wearable device.

According to an embodiment, the state information of the wearable device may include temperature information of the wearable device.

According to an embodiment, the method may include an operation of controlling the at least one thermoelectric module to not operate when the temperature information of the wearable device is equal to or less than a specified temperature.

According to an embodiment, the case device may further include a communication interface (e.g., the communication interface 320), and the method may include an operation of acquiring state information of the wearable device from the wearable device electrically connected to the communication interface.

According to an embodiment, the case device may further include at least one temperature sensor, and the method may include an operation of acquiring state information of the wearable device through the at least one temperature sensor.

What is claimed is:

1. A case device for a wearable electronic device, comprising:
a housing including an internal space for receiving a wearable electronic device;
a communication interface configured to communicably couple with the wearable electronic device;
at least one accommodating groove formed on an interior surface of the housing;
at least one thermoelectric module disposed in the internal space and partially exposed through the at least one accommodating groove;
a heat radiating member disposed adjacent to the at least one thermoelectric module;
a battery disposed inside the housing; and
at least one processor electrically coupled to the communication interface, the at least one thermoelectric module, the heat radiating member, and the battery, wherein the at least one processor is configured to:
acquire a state information of the wearable electronic device, and
control the at least one thermoelectric module according to the acquired state information of the wearable electronic device.

2. The case device of claim 1, wherein the state information of the wearable electronic device includes a temperature of the wearable electronic device.

3. The case device of claim 2, wherein the at least one processor is further configured to:
deactivate the at least one thermoelectric module when the temperature information of the wearable electronic device is less than or equal to a prespecified temperature threshold.

4. The case device of claim 1, wherein the state information of the wearable electronic device is acquired by receiving a transmission from the wearable electronic device via the communication interface.

5. The case device of claim 1, wherein the case device further includes at least one temperature sensor, and
wherein the temperature of the wearable electronic device when disposed in the internal space is acquired via the at least one temperature sensor.

6. The case device of claim 5, wherein the at least one temperature sensor is disposed proximate to the at least one thermoelectric module.

7. The case device of claim 1, wherein the at least one processor is further configured to:
acquire a battery state information of the case device, and
control the at least one thermoelectric module, based on at least one of the state information of the wearable device or the battery state information of the case device.

8. The case device of claim 1, wherein the heat radiating member includes at least one of a graphite sheet, a vapor chamber, or a heat pipe.

9. The case device of claim 1, wherein the housing includes at least one first opening passing through at least one surface of the housing.

10. The case device of claim 1, wherein the state information of the wearable electronic device includes a temperature information of a first leg portion and a second leg portion of the wearable electronic device.

11. The case device of claim 10, wherein the at least one accommodating groove includes a first accommodating groove formed on the interior surface, in which the first leg portion is insertable, and a second accommodation groove formed on the interior surface, into which the second leg portion is insertable.

12. The case device of claim 11, wherein the at least one thermoelectric module includes a first thermoelectric module disposed to be partially exposed through the first accommodating groove and a second thermoelectric module disposed to be partially exposed through the second accommodating groove, and
wherein the at least one processor is further configured to control the first thermoelectric module and the second thermoelectric module, based on at least one of the state information of the case device or the temperature information of the first leg portion and the second leg portion of the wearable electronic device.

13. The case device of claim 1, wherein the at least one thermoelectric module includes a Peltier element.

14. A case device for a wearable electronic device, comprising:
a housing including an internal space for receiving a wearable electronic device;
at least one accommodating groove formed on an interior surface of the case device for receiving the wearable electronic device, and dissipating heat of the wearable electronic device; and
a heat radiating member disposed in a position corresponding to the at least one accommodating groove, and exposed at least partially.

15. The case device of claim 14, wherein the heat radiating member includes at least one of a graphite sheet, a vapor chamber, or a heat pipe.

16. A method for operating a case device for a wearable electronic device, the method comprising:
acquiring a state information of the wearable electronic device accommodated in the case device; and
controlling the at least one thermoelectric module, based on the acquired state information of the wearable electronic device.

17. The method of claim 16, wherein the state information of the wearable electronic device includes a temperature information of the wearable electronic device.

18. The method of claim 17, further comprising:
deactivating the at least one thermoelectric module when the temperature information of the wearable electronic device is equal to or less than a prespecified temperature threshold.

19. The method of claim 16, wherein the case device further includes a communication interface, and
wherein the state information of the wearable electronic device is acquired from the wearable electronic device via communicable connection via the communication interface.

20. The method of claim 16, wherein the case device further includes at least one temperature sensor, and wherein the state information of the wearable electronic device is acquired through the at least one temperature sensor.
